(19) United States
(12) Patent Application Publication
(10) Pub. No.: US 2026/0096327 A1
(43) Pub. Date: Apr. 2, 2026

(54) DISPLAY PANEL AND DISPLAY DEVICE

(71) Applicant: HKC CORPORATION LIMITED, Shenzhen (CN)

(72) Inventors: Yao Li, Shenzhen (CN); Chuan Wu, Shenzhen (CN); Tianjun Huang, Shenzhen (CN); Zhonglin Cao, Shenzhen (CN); Xiaoxiao Yuan, Shenzhen (CN); Wenyu Yi, Shenzhen (CN); Fengzhen Dang, Shenzhen (CN); Dongmei Wei, Shenzhen (CN); Jie Chen, Shenzhen (CN); Haijiang Yuan, Shenzhen (CN)

(21) Appl. No.: 19/330,838

(22) Filed: Sep. 17, 2025

(30) Foreign Application Priority Data
Sep. 30, 2024 (CN) 202411391274.8

(51) Int. Cl. H10K 59/50

(52) U.S. Cl. CPC H10K 59/50

(57) ABSTRACT

A display panel and a display device are disclosed. The display panel includes a substrate, a pixel driving layer, a light-emitting element layer, a light modulation layer, and an encapsulation layer. The pixel driving layer is disposed on the substrate. The light-emitting element layer is disposed on the pixel driving layer. The light modulation layer is disposed on the light-emitting element layer. The encapsulation layer is disposed on the light modulation layer. The light modulation layer adjusts its transmittance based on a brightness of the light-emitting element layer. When the brightness of the light-emitting element layer is lower than a preset brightness, the light transmittance of the light modulation layer increases.

### CROSS-REFERENCE TO RELATED APPLICATIONS

This application claims the priority and benefit of Chinese patent application number 2024113912748, titled “Display Panel and Display Device” and filed Sep. 30, 2024 with China National Intellectual Property Administration, the entire contents of which are incorporated herein by reference.

### TECHNICAL FIELD

The present application relates to the field of display technology, and more particularly relates to a display panel and a display device.

### BACKGROUND

The description provided in this section is intended for the mere purpose of providing background information related to the present application but does not necessarily constitute prior art.

With the continuous development of OLED (Organic Light-Emitting Diode) display technology, OLED has been increasingly applied in displays of smartphones, tablets, computers, televisions, and the like. OLED displays have the advantages of being thin and lightweight, having high contrast, fast response, wide viewing angles, high brightness, and full-color display capabilities. However, a cathode in the OLED display panel is an active metal and is very sensitive to moisture and oxygen in the air. It is prone to reacting with moisture and oxygen that permeate from the external environment, thereby affecting charge injection. In addition, the permeated moisture and oxygen may chemically react with an organic light-emitting material in the light-emitting layer, damaging the organic light-emitting material and greatly reducing its luminous efficiency, which leads to degraded performance and shortened lifespan of the OLED display panel. Therefore, the OLED display panel requires high encapsulation reliability.

Furthermore, in addition to the performance degradation of the light-emitting elements caused by insufficient encapsulation, process-related factors in OLED fabrication may also result in different performance among different light-emitting elements, leading to non-uniform light-emitting brightness among different light-emitting elements under the same driving voltage.

### SUMMARY

It is therefore one purpose of the present application to provide a display panel and a display device. By providing a light modulation layer, non-uniform light-emitting brightness caused by process-related factors or moisture/oxygen ingress among light-emitting elements can be balanced, thereby improving the display effect of the display panel.

This application discloses a display panel. The display panel includes a substrate, a pixel driving layer, a light-emitting element layer, a light modulation layer, and an encapsulation layer. The pixel driving layer is disposed on the substrate. The light-emitting element layer is disposed on the pixel driving layer. The light modulation layer is disposed on the light-emitting element layer. The encapsulation layer is disposed on the light modulation layer. The light modulation layer adjusts a transmittance of the light modulation layer depending on the brightness of the light-emitting element layer. When the brightness of the light-emitting element layer is lower than a preset brightness, the light transmittance of the light modulation layer increases.

In some embodiments, when the brightness of the light-emitting element layer during light emission is not lower than a preset brightness, the light modulation layer is in a first state, and the light transmittance of the light modulation layer is a fixed value between 5% and 90%. When the brightness of the light-emitting element layer during light emission is lower than the preset brightness, the transmittance of the light modulation layer increases.

In some embodiments, the display panel includes a plurality of aperture regions and a plurality of non-aperture regions. The display panel further includes a plurality of pixel defining layers. The light-emitting element layer includes a plurality of light-emitting elements. Two adjacent light-emitting elements are separated by the corresponding pixel defining layer. The plurality of pixel defining layers are respectively arranged in the plurality of non-aperture regions. The plurality of light-emitting elements are respectively arranged in the plurality of aperture regions. The light modulation layer includes a sealing layer and a plurality of light modulation portions. The sealing layer includes a plurality of sealed cavities, where each sealed cavity contains one light modulation portion. Each of the plurality of sealed cavities is arranged to correspond to at least one of the plurality of aperture regions. The light transmittance of each light modulation portion is adjustable between 0% and 90%.

In some embodiments, each light modulation portion includes a thermally expandable temperature-sensitive hydrogel layer. The light modulation layer further includes a plurality of heating portions, and each of the plurality of heating portions is arranged to correspond to at least one of the plurality of aperture regions. Each heating portion is configured to provide heat to the corresponding thermally expandable temperature-sensitive hydrogel layer. Each thermally expandable temperature-sensitive hydrogel layer is configured to absorb different amounts of heat to produce different transmittance. The display panel further includes a control unit, which is configured to control each heating portion to heat up or cool down. When the light-emitting element layer normally emits light, the control unit controls each heating portion to heat to the initial preset temperature, so that the corresponding thermally expandable temperature-sensitive hydrogel layer is in the first state, and the light transmittance of the light modulation layer is at a fixed value between 5% and 90%. When the brightness of one of the light-emitting elements during normal emission is lower than the preset brightness, the control unit controls the heating portion in the aperture region where the light-emitting element is located to heat to a target temperature, so that the light transmittance of the thermally expandable temperature-sensitive hydrogel layer increases, where the target temperature is higher than the initial preset temperature.

In some embodiments, the light modulation layer further includes a thermal insulation layer. The thermal insulation layer surrounds the plurality of heating portions and the sealing layer, and is configured for heat insulation and heat preservation.

In some embodiments, each heating portion is formed of a wave-absorbing heating material configured to convert absorbed ultrasonic waves into a temperature rise.

In some embodiments, the thickness of each thermally expandable temperature-sensitive hydrogel layer is between 1 μm and 5 μm. The width of the orthographic projection of each thermally expandable temperature-sensitive hydrogel layer on the substrate is greater than or equal to the width of the orthographic projection of the corresponding aperture region on the substrate.

In some embodiments, when each light-emitting element is not emitting light, the control unit controls the corresponding heating portion to stop operating, so that the corresponding thermally expandable temperature-sensitive hydrogel layer is in the second state, and the light transmittance of the corresponding thermally expandable temperature-sensitive hydrogel layer is between 0% and 5%.

In some embodiments, the light-emitting element layer includes a plurality of red light-emitting elements, a plurality of green light-emitting elements, and a plurality of blue light-emitting elements. The red light-emitting elements, the green light-emitting elements, and the blue light-emitting elements are respectively disposed within the plurality of aperture regions. Within the range of the orthographic projection of each sealed cavity on the substrate, at least one aperture region is covered. The display panel further includes a color filter layer. The color filter layer includes a plurality of black matrices and a plurality of color filter portions. The plurality of black matrices are respectively disposed in the plurality of non-aperture regions. The plurality of color filter portions are respectively disposed in the plurality of aperture regions.

The present application further discloses a display device, including a driving circuit and the above-mentioned display panel, where the driving circuit is configured to drive the display panel for display.

In the present application, by setting a light modulation layer and utilizing the ability of the light modulation layer to adjust light transmittance, when the light transmittance of the light modulation layer increases, the corresponding capability of the light passing through the light modulation layer becomes stronger, and the corresponding brightness becomes higher. When the light-emitting elements in the display panel have different light-emitting brightness under the same driving voltage due to process-related reasons or moisture and oxygen intrusion caused by encapsulation failure, the brightness difference of the light-emitting elements is balanced by adjusting the light transmittance of the light modulation layer disposed on the light-emitting elements. When the light-emitting elements emit light, the transmittance of the light modulation layer is normally adjusted to a fixed value. When the brightness of the light emitted by a light-emitting element is detected to be relatively low or below a preset brightness, the brightness of the light-emitting element is enhanced by increasing the light transmittance of the light modulation layer at that position. Thus, the uneven light-emitting brightness of the light-emitting elements caused by the process-related factors and moisture-oxygen intrusion is balanced, thereby improving the display effect of the display panel. Moreover, in this embodiment, the light modulation layer is arranged between the encapsulation layer and the light-emitting element layer, thus buffering the protruding fine particles generated in the light-emitting element layer during the manufacturing process from causing pinholes or cracks in the inorganic layer of the encapsulation layer, thereby improving the encapsulation capability of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel according to the present application.

FIG. 2 is a schematic diagram of a light modulation layer according to the present application.

FIG. 3 is a schematic diagram of another display panel according to the present application.

FIG. 4 is a top view schematic diagram of a thermally expandable temperature-sensitive hydrogel layer according to the present application.

FIG. 5 is a schematic diagram of another display panel according to the present application.

FIG. 6 is a schematic diagram of a display device according to the present application.

In the drawings: 100, display panel; 101, aperture region; 102, non-aperture region; 110, substrate; 120, pixel driving layer; 130, light-emitting element layer; 131, light-emitting element; 140, encapsulation layer; 150, light modulation layer; 151, sealing layer; 1511, sealed cavity; 152, light modulation portion; 1521, thermally expandable temperature-sensitive hydrogel layer; 153, heating portion; 154, thermal insulation layer; 160, pixel defining layer; 170, color filter layer; 171, color filter portion; 172, black matrix; 180, control unit; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

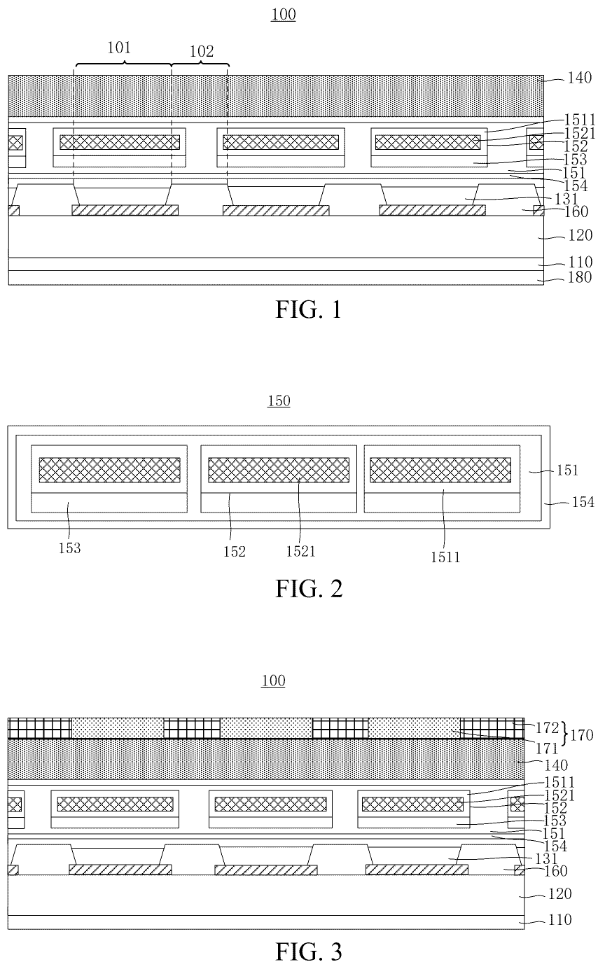

FIG. 1 is a schematic diagram of a display panel according to the present application. FIG. 2 is a schematic diagram of a light modulation layer according to the present application. Referring to FIGS. 1 and 2, the present application discloses a display panel 100. The display panel 100 includes a substrate 110, a pixel driving layer 120, a light-emitting element layer 130, a light modulation layer 150, and an encapsulation layer 140. The pixel driving layer 120 is disposed on the substrate 110. The light-emitting element layer 130 is disposed on the pixel driving layer 120. The light modulation layer 150 is disposed on the light-emitting element layer 130. The encapsulation layer 140 is disposed on the light modulation layer 150. The light modulation layer 150 adjusts its transmittance depending on the brightness of the light-emitting element layer 130. When the brightness of the light emitted by the light-emitting element layer 130 is lower than a preset brightness, the light transmittance of the light modulation layer 150 increases.

In the present application, by providing the light modulation layer 150 and utilizing its ability to adjust light transmittance, when the light transmittance of the light modulation layer 150 increases, the corresponding efficiency of light passing through the light modulation layer 150 is higher, and the corresponding brightness is greater. When the light-emitting elements 131 in the display panel 100 have different light-emitting brightness under the same driving voltage due to process-related reasons or moisture and oxygen intrusion caused by encapsulation rupture, the brightness difference of the light-emitting elements 131 is balanced by adjusting the light transmittance of the light modulation layer 150 disposed on the light-emitting elements 131. When the light-emitting elements 131 emit light, the transmittance of the light modulation layer 150 is normally adjusted to a fixed value. When it is detected that the light brightness emitted by a light-emitting element 131 is relatively low or below a preset brightness, the brightness of the light-emitting element 131 is increased by increasing the light transmittance of the light modulation layer 150 at that position. This achieves balancing the uneven light-emitting brightness of the light-emitting elements 131 caused by the manufacturing process and moisture/oxygen intrusion, thereby enhancing the display effect of the display panel 100. Moreover, in this embodiment, the light modulation layer 150 is arranged between the encapsulation layer 140 and the light-emitting element layer 130, which can buffer the protruding fine particles generated by the light-emitting element layer 130 during the manufacturing process from causing pinholes or cracks in the inorganic layer of the encapsulation layer 140, thereby enhancing the encapsulation capability of the display panel 100.

It can be understood that during testing, the light modulation layer 150 in the display panel 100 has an initial light transmittance. That is, when the plurality of light-emitting elements 131 emit light, the light modulation layer 150 at different positions has the same light transmittance. When it is detected that the brightness of a light-emitting element 131 is relatively low, the light transmittance at the corresponding position of the light modulation layer 150 is adjusted to achieve an increase in brightness at that position. An advantage of this embodiment is that it does not require subsequent voltage compensation for the light-emitting element 131; instead, control of the light-emitting element 131 is achieved directly through the optical film layer, reducing the complexity of subsequent circuit compensation.

In this embodiment, the light modulation layer 150 can independently control the light transmittance at each position. By controlling the light modulation layer 150 on a per-partition basis, specific adjustment of light transmittance at different positions is achieved.

In one embodiment, the display panel 100 includes a plurality of aperture regions 101 and a plurality of non-aperture regions 102. The display panel 100 further includes a plurality of pixel defining layers 160. The light-emitting element layer 130 includes a plurality of light-emitting elements 131. Two adjacent light-emitting elements 131 are separated by the corresponding pixel defining layer 160. Each pixel defining layer 160 is disposed in the corresponding non-aperture region 102. The plurality of light-emitting elements 131 are respectively disposed in the plurality of aperture regions 101.

The display panel 100 may include a plurality of display partitions. At least one sub-pixel or one light-emitting element 131 is arranged in each display partition. At least one sub-pixel or one light-emitting element 131 is arranged in each display partition. One light-emitting element 131 may be arranged within one aperture region 101, which corresponds to one sub-pixel. Three sub-pixels of different colors collectively constitute one pixel. In this embodiment, the light modulation portion 152 can correspond to at least one sub-pixel. In practical applications, the area of one light modulation portion 152 can be set larger. For example, it can correspond to one pixel or multiple pixels, reducing process costs and thereby achieving lower cost.

Specifically, one light-emitting element 131 as one display partition is taken as an example for illustration.

The light modulation layer 150 includes a sealing layer 151 and a plurality of light modulation portions 152. The sealing layer 151 includes a plurality of sealed cavities 1511. Each sealed cavity 1511 contains one light modulation portion 152, and each of the plurality of sealed cavities 1511 is disposed to correspond to at least one of the plurality of aperture regions 101.

In one aperture region 101, one light-emitting element 131 and one light modulation portion 152 are arranged. When a light-emitting element 131 in the display panel 100 has a low brightness due to process-related reasons or encapsulation failure, the light transmittance of the light modulation portion 152 in the aperture region 101 where the light-emitting element 131 is located can be adjusted to enhance the light-emitting brightness of the light-emitting element 131.

The main structure of the light modulation portion 152 in this embodiment uses a thermally expandable temperature-sensitive hydrogel material, which undergoes a phase transition reaction in response to temperature changes. The hydrogel material is synthesized from monomers or polymers by forming a water-permeable crosslinked network. A polymer is formed by polymerizing monomers, and then through a gelation process (crosslinking method), an interpenetrating polymer network (IPN) is formed. The crosslinking of the gel network can be divided into non-covalent bonds (i.e., physical crosslinking) or covalent bonds (i.e., chemical crosslinking). Hydrogels may be jelly-like solids with elasticity.

Polymeric hydrogel material can be defined as a crosslinked polymer that swells in water, retains a large amount of water, and cannot be dissolved. The forces that induce phase transition in polymers can be classified into four types: hydrophobic interaction, hydrophilic interaction (including hydrogen bonding and water solvation), van der Waals force, and electrostatic interaction between ions. With changes in the external environment, these four forces compete with each other, causing the conformation of polymer chain segments in the solution to change, ultimately leading to phase transition.

When a macromolecular chain has both hydrophilic and hydrophobic groups, the linear polymer in an aqueous solution undergoes a change in molecular chain conformation with temperature variation, transitioning from an extended random coil to a coiled globular shape. This conformation change may be considered to be the result of the competition between hydrophilic interaction and hydrophobic interaction. For example, substances such as polypropylene amine and polyacrylic acid exhibit thermal expansion temperature sensitivity. A chitosan-based hydrogel polymer derived from such macromolecules can be adjusted in composition to exhibit phase transition capability at different temperatures, and its light transmittance varies with different degrees of phase transition.

Specifically, the light modulation portion 152 includes a plurality of thermally expandable temperature-sensitive hydrogel layers 1521. The light modulation layer 150 further includes a plurality of heating portions 153. Each of the plurality of heating portions 153 is disposed to correspond to at least one of the plurality of aperture regions 101. Each of the heating portions 153 is used to provide heat to the corresponding thermally expandable temperature-sensitive hydrogel layer 1521. Each of the thermally expandable temperature-sensitive hydrogel layers 1521 absorbs different amounts of heat to produce varying levels of transmittance.

The plurality of thermally expandable temperature-sensitive hydrogel layers 1521 are respectively disposed within the plurality of sealed cavities 1511. A salt solution is further disposed within each of the sealed cavities 1511. The sealing layer 151 is disposed over the plurality of heating portions 153. Because the thermally expandable temperature-sensitive hydrogel layer 1521 has a better phase transition effect in the solution, it can be sealed with the salt solution to achieve encapsulation of the thermally expandable temperature-sensitive hydrogel layer 1521. The material of the sealing layer 151 can be a polymeric polyethylene-based material, thus forming a flexible sealed cavity 1511. In the sealed cavity 1511, a salt solution and a thermally expandable temperature-sensitive hydrogel material can be arranged. In this embodiment, the light modulation layer 150 or the sealing layer 151 can be configured as a membrane and attached to one side of the cover plate of the display panel 100 adjacent to the substrate 110 or to the encapsulation layer 140.

In this embodiment, the light transmittance of the thermally expandable temperature-sensitive hydrogel layer 1521 is primarily adjusted through the heating portion 153, so that the thermally expandable temperature-sensitive hydrogel layer 1521 has different temperatures, resulting in different phase transitions. For example, when the thermally expandable temperature-sensitive hydrogel layer 1521 is in the temperature range of 25° C. to 40° C., the thermally expandable temperature-sensitive hydrogel layer 1521 is in the first state. For another example, when the thermally expandable temperature-sensitive hydrogel layer 1521 is in the temperature range of 0° C. to 25° C., the thermally expandable temperature-sensitive hydrogel layer 1521 is in the second state.

When the thermally expandable temperature-sensitive hydrogel layer 1521 is in the first state, its transmittance can continuously vary between 5% and 90%. Specifically, it can be divided into two stages. For example, when the thermally expandable temperature-sensitive hydrogel layer 1521 is in the first temperature range of 25° C. to 30° C., as the temperature increases, the transmittance increases either linearly or non-linearly, gradually rising between 5% and 30%. However, when the temperature rises to the second temperature range of 30° C. to 40° C., the thermally expandable temperature-sensitive hydrogel layer 1521 undergoes a sharp phase transition, causing the transmittance to jump from 30% to 80% or 90%. That is, when the temperature of the thermally expandable temperature-sensitive hydrogel layer 1521 is within the second temperature range, it maintains a relatively high transmittance, resulting in a higher transmittance for the display panel 100. When the thermally expandable temperature-sensitive hydrogel layer 1521 is in the second state, the hydrogel material in the light modulation portion 152 is in a globular state. Although there is 5% transmittance, due to light refraction and scattering, the light emitted by the corresponding light-emitting element 131 is significantly reduced, resulting in extremely low brightness.

Specifically, the display panel 100 further includes a control unit 180, which is used to control the heating portion 153 to heat up or cool down, so that the light transmittance of the light modulation portion 152 can be adjusted between 0% and 90%. It is worth mentioning that in the ideal state, the light transmittance of the light modulation portion can be as high as close to 100%.

Specifically, when the control unit 180 controls the heating portion 153 to be inactive, the thermally expandable temperature-sensitive hydrogel layer 1521 is at a normal temperature, for example, in the range of 0° C. to 25° C., and the light transmittance of the thermally expandable temperature-sensitive hydrogel layer 1521 is between 0% and 5%. When the display panel 100 is displaying and the light-emitting element layer 130 is emitting light normally, the control unit 180 controls the heating portion 153 to heat up to the initial preset temperature. The thermally expandable temperature-sensitive hydrogel layer 1521 is in the first state, and the light transmittance of the light modulation layer 150 is at a fixed value between 5% and 90%. When the brightness of a light-emitting element 131 emitting light normally is lower than the preset brightness, the control unit 180 controls the heating portion 153 in the aperture region 101 where the light-emitting element 131 is located to heat up to the target temperature, so that the light transmittance of the thermally expandable temperature-sensitive hydrogel layer 1521 increases, where the target temperature is higher than the initial preset temperature.

In this embodiment, when the light-emitting element layer 130 is emitting light normally, the control unit 180 controls the heating portion 153 to heat up to the initial preset temperature. The thermally expandable temperature-sensitive hydrogel layer 1521 is in the first state, and the light transmittance of the light modulation layer 150 is fixed between 5% and 90%. When the brightness of a light-emitting element 131 emitting light normally is lower than the preset brightness, the control unit 180 controls the heating portion 153 in the aperture region 101 where the light-emitting element 131 is located to heat up to the target temperature, thereby increasing the light transmittance of the thermally expandable temperature-sensitive hydrogel layer 1521, where the target temperature is greater than the initial preset temperature. The above-mentioned temperature ranges can actually be adjusted by modifying the components in the thermally expandable temperature-sensitive hydrogel layer 1521, so that the thermally expandable temperature-sensitive hydrogel layer 1521 has different temperatures under the same light transmittance. It can be specifically designed according to the actual situation, and in this embodiment, the above-mentioned temperature ranges are only used for illustration and the present application is not to be limited to the above temperature range.

The target temperature may be within the first temperature range to the second temperature range, and the initial preset temperature may be within the first temperature range. It can be understood that the target temperature in this application can be a dynamic value, thereby dynamically adjusting the light transmittance based on the brightness of the light-emitting element 131. The preset initial temperature of the light-emitting element 131 can be selected based on actual conditions. For example, if the light transmittance of the light modulation portion 152 is set at 10%, the second target temperature should correspond to a light transmittance greater than 10%. With regards to the brightness of the light-emitting element 131, the detected brightness can be compared with the grayscale controlling the light-emitting element 131 to determine whether the brightness of the light-emitting element 131 is lower than the grayscale brightness.

In another embodiment, when a light-emitting element 131 is not emitting light, the control unit 180 controls the heating portion 153 to be inactive, causing the thermally expandable temperature-sensitive hydrogel layer 1521 to be in the second state, with the light transmittance of the thermally expandable temperature-sensitive hydrogel layer 1521 ranging from 0% to 5%.

When a light-emitting element 131 fails significantly, leading to no light emission, low light emission, or becoming a bright spot, this application can control the thermally expandable temperature-sensitive hydrogel layer 1521 at the location of the light-emitting element 131 to a temperature range of 0° C. to 25° C., resulting in a light transmittance of the thermally expandable temperature-sensitive hydrogel layer 1521 ranging from 0% to 5%. At this time, the hydrogel material in the light modulation portion 152 is in a globular state. Although there is 5% transmittance, due to light refraction and scattering, the light-emitting element 131 emits almost no light, causing the location to become a pixel dark spot and preventing the occurrence of a bright spot.

FIG. 3 is a schematic diagram of another display panel according to the present application. Referring to FIG. 3, when the display panel 100 of the present application is a COE display panel 100, COE (Color film on Encapsulation, where a color filter is formed on the thin-film encapsulation structure) is a new technology that replaces the polarizer. The transmittance of the color filter can reach up to 60%, which significantly increases the light output brightness, thus reducing the power consumption of the OLED device and improving its lifespan. The display panel 100 further includes a color filter layer 170. The color filter layer 170 includes a plurality of black matrices 172 and a plurality of color filter portions 171. The plurality of black matrices 172 are respectively arranged in the plurality of non-aperture regions 102. The plurality of color filter portions 171 are respectively arranged in the plurality of aperture regions 101. When a light-emitting element 131 of the display panel 100 does not emit light, the light transmittance of the corresponding thermally expandable temperature-sensitive hydrogel layer 1521 is controlled to be between 0% and 5%. The light entering from the external environment and reflected by the metal electrode inside the display panel 100 is minimal, reducing the ambient light reflection issue at that location. It can effectively absorb ambient light, preventing ambient light from entering the interior of the display panel 100 and being reflected by the metal electrode, which would otherwise cause color separation or glare issues, thus improving the display effect of the display panel 100.

In one embodiment, the light modulation layer 150 (also referring to FIG. 2) further includes a thermal insulation layer 154. The thermal insulation layer 154 wraps around the plurality of heating portions 153 and the sealing layer 151. The thermal insulation layer 154 is used for heat insulation and heat preservation. The thermal insulation layer 154 serves the functions of heat preservation and insulation. When the heating portion 153 heats the thermally expandable temperature-sensitive hydrogel layer 1521, the thermal insulation layer 154 helps maintain the temperature of the thermally expandable temperature-sensitive hydrogel layer 1521. This keeps the thermally expandable temperature-sensitive hydrogel layer 1521 in the second state or third state. The thermal insulation layer 154 can be made of transparent inorganic or organic polymer materials, such as zirconia ceramic material, polyester, polyimide film, etc. The excellent thermal insulation performance of the above materials can also minimize the impact of ambient temperature on the thermally expandable temperature-sensitive hydrogel layer 1521.

In this embodiment, the control unit 180 controls the heating portion 153 to adjust the thermally expandable temperature-sensitive hydrogel layer 1521. For the material selection of the heating portion 153, a resistive heating element can be used. The thermally expandable temperature-sensitive hydrogel layer 1521 is heated through resistive heating, controlled electrically. The advantage lies in high accuracy and strong controllability, but it requires circuit design, which adds complexity.

In another embodiment, the heating portion 153 can also use a wave-absorbing heating material, which absorbs ultrasonic waves and converts them into a rise in temperature. A wave-absorbing material is capable of absorbing or attenuating the electromagnetic wave energy projected onto its surface and converting this energy into heat or other forms through dielectric loss or magnetic loss in the material. The wave-absorbing heating material includes graphene/vanadium dioxide composite aerogel material or ceramic wave-absorbing fiber material. The graphene/vanadium dioxide composite aerogel material has a heating function under ultrasonic waves and exhibits different temperature rise gradients for ultrasonic waves of different wavelengths. For example, the longer the wavelength, the higher the temperature rise. Of course, ultrasonic waves of the same wavelength can also be used, and by adjusting the time parameter, the heating portion 153 can reach the target temperature. The representative ceramic wave-absorbing fiber material is silicon carbide (SiC). In SiC, the wavelength range from 2 GHz to 7 GHz is the low absorption frequency band with low absorption level for ultrasonic waves. The wavelength range from 8 GHz to 18 GHz is the high absorption frequency band, with the absorption level for ultrasonic waves reaching up to 90%. By adjusting the wavelength and the time parameter, rapid heating to the target temperature can be achieved.

The aforementioned wave-absorbing heating material requires absorption of a wave source from the external environment to generate heat. The frequency, wave intensity, and time of the ultrasonic wave will affect the temperature conversion of the wave-absorbing material. Therefore, by adjusting these parameters, the heat change of the thermally expandable temperature-sensitive hydrogel layer 1521 can be achieved. After heating, the presence of the thermal insulation layer 154 will also maintain the internal temperature, ensuring the phase transition stability of the hydrogel. The control unit 180 can be an ultrasonic emission structure, disposed on the back side of the display panel 100 or on the housing.

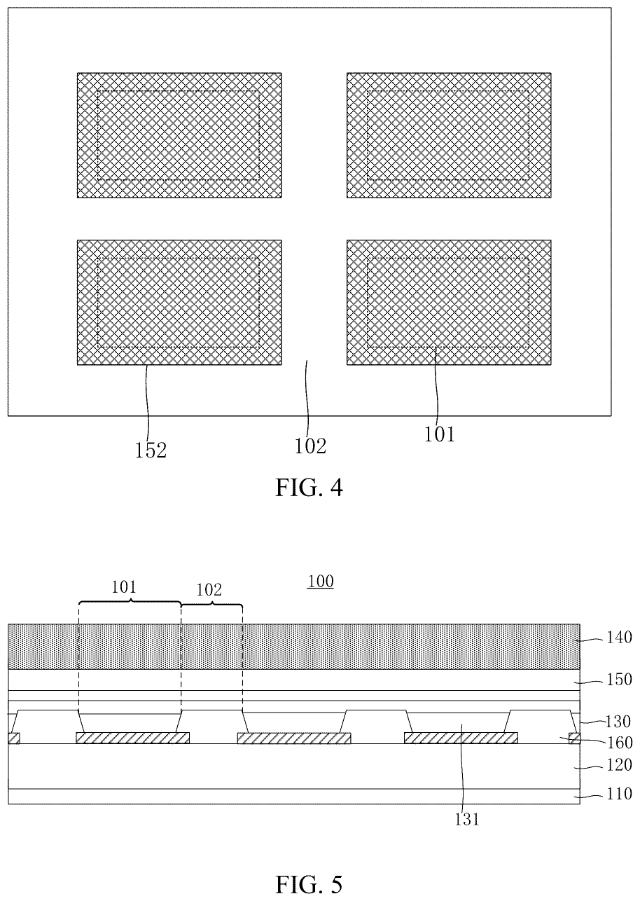

FIG. 4 is a top view schematic diagram of a thermally expandable temperature-sensitive hydrogel layer in this application. Referring to FIG. 4, the thickness of the thermally expandable temperature-sensitive hydrogel layer 1521 (as illustrated in FIG. 3) is between 1 μm and 5 μm. Under the orthographic projection on the substrate 110, the width of the projection of each thermally expandable temperature-sensitive hydrogel layer 1521 is greater than or equal to the width of the corresponding aperture region 101. In this embodiment, the width of each thermally expandable temperature-sensitive hydrogel layer 1521 is appropriately larger than the width of the corresponding aperture region 101 where the light-emitting element 131 is located, so that the light emitted by the light-emitting element 131 needs to pass through the light modulation portion 152.

In another embodiment, the number of light-emitting elements 131 corresponding to the light modulation portion 152 within a sealed cavity 1511 can also be multiple. For example, the light-emitting element layer 130 includes a plurality of red light-emitting elements 131, a plurality of green light-emitting elements 131, and a plurality of blue light-emitting elements 131. The plurality of red light-emitting elements 131, the plurality of green light-emitting elements 131, and the plurality of blue light-emitting elements 131 are respectively disposed within the corresponding multiple aperture regions 101. In the orthographic projection of the substrate 110, three of the aperture regions 101 can be arranged within the projection range of a sealed cavity 1511. In the three aperture regions 101, a red light-emitting element 131, a green light-emitting element 131, and a blue light-emitting element 131 are respectively arranged.

FIG. 5 is a schematic diagram of another display panel according to the present application. Referring to FIG. 5, the light modulation layer 150 of the present application may also be controlled as a whole. For example, when the display panel 100 is displaying a high brightness, the light modulation layer 150 is controlled to have a relatively higher light transmittance. When the display panel 100 is displaying a low brightness, especially when it is not displaying, the light modulation layer 150 is controlled to have a relatively lower light transmittance. When the display panel 100 performs high grayscale display, the light modulation layer 150 is adjusted to have a relatively higher light transmittance. Even if ambient light enters the interior of the display panel 100 at this time, the influence of the ambient light on the display effect is minimal due to the high grayscale of the display. The original emitted light is not affected, and thus the display effect is not compromised.

Specifically, when the light-emitting element layer 130 emits light normally, the light modulation layer 150 is in a first state, and the light transmittance of the light modulation layer 150 is a fixed value in the range of 5% to 90%. When the brightness of the light-emitting element layer 130 during normal emission is lower than the preset brightness, the transmittance of the light modulation layer 150 increases.

In another embodiment, when the light-emitting element layer 130 does not emit light, the light modulation layer 150 is in a second state, and the light transmittance of the light modulation layer 150 is in the range of 0% to 5%.

It can be understood that the method of dynamically adjusting the light transmittance in this embodiment is also applicable to the above-mentioned partitioned embodiment. Specifically, when the thermally expandable temperature-sensitive hydrogel layer 1521 is in the first state, the fixed value of the light transmittance of the light modulation layer 150 in the range of 5% to 90% may be changed to a dynamic value.

Specifically, the adjustment can be dynamically performed based on the light-emitting brightness of the light-emitting element layer 130. The light-emitting intensity of the light-emitting element layer 130 can be determined according to the grayscale. In a grayscale range of 0 to 255, a higher grayscale value indicates a greater light-emitting intensity of the light-emitting element layer 130, while a lower grayscale value indicates a smaller light-emitting intensity. Therefore, the light-emitting intensity of the light-emitting element layer 130 can be determined by determining the display grayscale of the display panel 100. In this embodiment, a grayscale in the range of 0 to 127 is defined as a low grayscale, and a grayscale in the range of 128 to 255 is defined as a high grayscale.

For example, when the grayscale of the display panel 100 is in the range of 0 to 127, the control unit 180 controls the heating portion 153 to raise the temperature to the first temperature range. For example, when the temperature is between 25° C. and 30° C., the thermally expandable temperature-sensitive hydrogel layer 1521 is in the first state, and the transmittance can continuously vary between 5% and 90%. For another example, when the grayscale of the display panel 100 is in the range of 127 to 255, the control unit 180 controls the heating portion 153 to raise the temperature to the second temperature range, for instance, between 30° C. and 40° C., and the thermally expandable temperature-sensitive hydrogel layer 1521 remains in the first state. At this time, the thermally expandable temperature-sensitive hydrogel layer 1521 undergoes a rapid phase transition, and its transmittance abruptly increases from 30% to 80% or 90%. That is, when the temperature of the thermally expandable temperature-sensitive hydrogel layer 1521 is within the second temperature range, it basically maintains a high transmittance, enabling the display panel 100 to have a high transmittance.

In this embodiment, by providing the light modulation layer 150 and utilizing its function of adjustable transmittance, when the display panel 100 is not displaying or displaying at a low grayscale, the light modulation layer 150 is adjusted to a lower transmittance, so that external ambient light enters the interior of the display panel 100 as little as possible, thereby effectively absorbing the external ambient light, making the display panel 100 have a darker black state when not displaying, and preventing glare issues during low brightness display. When the display panel 100 performs high grayscale display, the light modulation layer 150 is adjusted to a higher transmittance. At this time, even if ambient light enters the interior of the display panel 100, the impact of the ambient light on the display effect is minimal due to the higher display grayscale of the display panel 100, and it will not affect the original emitted light, thus not affecting the display effect. In this application, by setting the light modulation layer 150, the design of a polarizer or color filter can be eliminated. The transmittance of the light modulation layer 150 is adjusted to filter external ambient light, thereby improving the quality of the display panel 100.

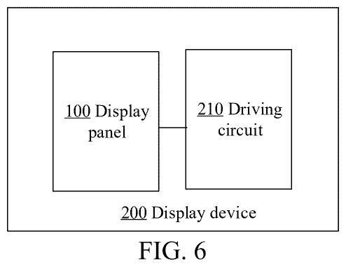

FIG. 6 is a schematic diagram of a display device in this application. Referring to FIG. 6, this application further discloses a display device 200. The display device 200 includes a driving circuit 210 and a display panel 100, which can be any of the display panels described in the foregoing embodiments. The driving circuit is used to drive the display panel 100 for display.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising:
a substrate;
a pixel driving layer, disposed on the substrate;
a light-emitting element layer, disposed on the pixel driving layer;
a light modulation layer, disposed on the light-emitting element layer; and
an encapsulation layer, disposed on the light modulation layer;
wherein the light modulation layer is configured to adjust a transmittance of the light modulation layer depending on a brightness of the light-emitting element layer; and in response to the brightness of the light-emitting element layer being lower than a preset brightness, the transmittance of the light modulation layer is increased.

2. The display panel as recited in claim 1, wherein in response to the brightness of the light-emitting element layer not being lower than the preset brightness, the light modulation layer is in a first state, and the light transmittance of the light modulation layer is at a fixed value that lies in a range between 5% and 90%;
in response to the brightness of the light-emitting element layer being lower than the preset brightness, the transmittance of the light modulation layer is increased.

3. The display panel as recited in claim 1, wherein the display panel comprises a plurality of aperture regions and a plurality of non-aperture regions, and further comprises a plurality of pixel defining layers;
wherein the light-emitting element layer comprises a plurality of light-emitting elements, and every two adjacent light-emitting elements are separated by a corresponding pixel defining layer, wherein the plurality of pixel defining layers are respectively disposed in the plurality of non-aperture regions, wherein the plurality of light-emitting elements are respectively disposed in the plurality of aperture regions;
wherein the light modulation layer comprises a sealing layer and a plurality of light modulation portions, wherein the sealing layer comprises a plurality of sealed cavities, each sealed cavity comprising one light modulation portion, and each of the plurality of sealed cavities being disposed to correspond to at least one of the plurality of aperture regions; wherein the light transmittance of each of the plurality of light modulation portions is adjustable between 0% and 90%.

4. The display panel as recited in claim 3, wherein the display panel comprises a plurality of display partitions, each of which comprises a light-emitting element, and wherein each of the plurality of light modulation portions corresponds to at least one of the plurality of display partitions.

5. The display panel as recited in claim 3, wherein each of the plurality of light modulation portions comprises a thermally expandable temperature-sensitive hydrogel layer, the light modulation layer further comprises a plurality of heating portions, each of which is disposed to correspond to at least one of the plurality of aperture regions, wherein each of the plurality of heating portions is configured to supply heat to a respective thermally expandable temperature-sensitive hydrogel layer, and wherein each thermally expandable temperature-sensitive hydrogel layer is configured to absorb different amounts of heat to create different transmittances;
wherein the display panel further comprises a control unit configured to control each of the plurality of heating portions to heat up or cool down;
in response to the light-emitting element layer emitting light normally, the control unit is configured to control each of the plurality of heating portions to heat up to an initial preset temperature, thereby causing the respective thermally expandable temperature-sensitive hydrogel layer to be in a first state, making the light transmittance of the light modulation layer a fixed value between 5% and 90%;
in response to the brightness of a light-emitting element being lower than the preset brightness, the control unit is configured to control the heating portion in the corresponding aperture region of the light-emitting element to heat up to a target temperature, thereby causing the respective thermally expandable temperature-sensitive hydrogel layer to increase its light transmittance, wherein the target temperature is higher than the initial preset temperature.

6. The display panel as recited in claim 5, wherein the light modulation layer further comprises a thermal insulation layer, the thermal insulation layer encapsulating the plurality of heating portions and the sealing layer, the thermal insulation layer being configured to provide thermal insulation and heat preservation.

7. The display panel as recited in claim 5, wherein each of the plurality of heating portions comprises a wave-absorbing heating material configured to convert absorbed ultrasonic waves into a temperature rise.

8. The display panel as recited in claim 5, wherein a thickness of each thermally expandable temperature-sensitive hydrogel layer lies in a range between 1 μm and 5 μm;
wherein a width of an orthographic projection of each thermally expandable temperature-sensitive hydrogel layer on the substrate is greater than or equal to a width of an orthographic projection of a respective aperture region on the substrate.

9. The display panel as recited in claim 5, wherein in response to a light-emitting element not emitting light, the control unit is configured to control a respective heating portion not to operate, causing a respective thermally expandable temperature-sensitive hydrogel layer to be in a second state, wherein the light transmittance of the respective thermally expandable temperature-sensitive hydrogel layer lies in a range between 0% and 5%.

10. The display panel as recited in claim 5, wherein each thermally expandable temperature-sensitive hydrogel layer has a light transmittance that lies in a range between 5% and 30% within a first temperature range of 25° C. to 30° C.;
wherein each thermally expandable temperature-sensitive hydrogel layer has a light transmittance that lies in a range between 80% and 90% within a second temperature range of 30° C. to 40° C.

11. The display panel as recited in claim 10, wherein the target temperature lies within the first temperature range to the second temperature range.

12. The display panel as recited in claim 3, wherein the light-emitting element layer comprises a plurality of red light-emitting elements, a plurality of green light-emitting elements, and a plurality of blue light-emitting elements; wherein the plurality of red light-emitting elements, the plurality of green light-emitting elements, and the plurality of blue light-emitting elements are respectively disposed in the plurality of aperture regions;
wherein an orthographic projection of at least one aperture region on the substrate is covered within a range of an orthographic projection of each sealed cavity on the substrate;
wherein the display panel further comprises a color filter layer, wherein the color filter layer comprises a plurality of black matrices and a plurality of color filter portions, with the plurality of black matrices being respectively arranged in the plurality of non-aperture regions and the plurality of color filter portions being respectively arranged in the plurality of aperture regions.

13. A display device, comprising a driving circuit and a display panel, wherein the driving circuit is configured to drive the display panel for display, wherein the display panel comprises:
a substrate;
a pixel driving layer, disposed on the substrate;
a light-emitting element layer, disposed on the pixel driving layer;
a light modulation layer, disposed on the light-emitting element layer; and
an encapsulation layer, disposed on the light modulation layer;
wherein the light modulation layer is configured to adjust a transmittance of the light modulation layer depending on a brightness of the light-emitting element layer; and in response to the brightness of the light-emitting element layer being lower than a preset brightness, the transmittance of the light modulation layer is increased.

14. The display device as recited in claim 13, wherein in response to the brightness of the light-emitting element layer not being lower than the preset brightness, the light modulation layer is in a first state, and the light transmittance of the light modulation layer is at a fixed value that lies in a range between 5% and 90%;
in response to the brightness of the light-emitting element layer being lower than the preset brightness, the transmittance of the light modulation layer is increased.

15. The display device as recited in claim 13, wherein the display panel comprises a plurality of aperture regions and a plurality of non-aperture regions, wherein the display panel further comprises a plurality of pixel defining layers;
wherein the light-emitting element layer comprises a plurality of light-emitting elements, and every two adjacent light-emitting elements are separated by a corresponding pixel defining layer, wherein the plurality of pixel defining layers are respectively disposed in the plurality of non-aperture regions, wherein the plurality of light-emitting elements are respectively disposed in the plurality of aperture regions;
wherein the light modulation layer comprises a sealing layer and a plurality of light modulation portions, wherein the sealing layer comprises a plurality of sealed cavities, each sealed cavity comprising one light modulation portion, and each of the plurality of sealed cavities being disposed to correspond to at least one of the plurality of aperture regions; wherein the light transmittance of the light modulation portions is adjustable between 0% and 90%.

16. The display device as recited in claim 15, wherein each of the plurality of light modulation portions comprises a thermally expandable temperature-sensitive hydrogel layer; wherein the light modulation layer further comprises a plurality of heating portions, each of the plurality of heating portions is disposed to correspond to at least one of the plurality of aperture regions; wherein each of the plurality of heating portions is configured to provide heat to a respective thermally expandable temperature-sensitive hydrogel layer, and wherein each thermally expandable temperature-sensitive hydrogel layer is configured to absorb different amounts of heat to create different transmittances;
wherein the display panel further comprises a control unit configured to control each of the plurality of heating portions to heat up or cool down;
in response to the light-emitting element layer emitting light normally, the control unit is configured to control each of the plurality of heating portions to heat up to an initial preset temperature, thereby causing the respective thermally expandable temperature-sensitive hydrogel layer to be in a first state, making the light transmittance of the light modulation layer a fixed value between 5% and 90%;
in response to the brightness of a light-emitting element being lower than the preset brightness, the control unit is configured to control the heating portion in the corresponding aperture region of the light-emitting element to heat up to a target temperature, thereby causing the respective thermally expandable temperature-sensitive hydrogel layer to increase its light transmittance, wherein the target temperature is higher than the initial preset temperature.

17. The display device as recited in claim 16, wherein the light modulation layer further comprises a thermal insulation layer, the thermal insulation layer encapsulating the plurality of heating portions and the sealing layer, the thermal insulation layer being configured to provide thermal insulation and heat preservation.

18. The display device as recited in claim 16, wherein each of the plurality of heating portions comprises a wave-absorbing heating material configured to convert absorbed ultrasonic waves into a temperature rise.

19. The display device as recited in claim 16, wherein a thickness of each thermally expandable temperature-sensitive hydrogel layer lies in a range between 1 μm and 5 μm;
wherein a width of an orthographic projection of each thermally expandable temperature-sensitive hydrogel layer on the substrate is greater than or equal to a width of an orthographic projection of a respective aperture region on the substrate.

20. The display device as recited in claim 16, wherein in response to a light-emitting element not emitting light, the control unit is configured to control a respective heating portion not to operate, causing a respective thermally expandable temperature-sensitive hydrogel layer to be in a second state, wherein the light transmittance of the respective thermally expandable temperature-sensitive hydrogel layer lies in a range between 0% and 5%.
